(19) United States
(12) Patent Application Publication
(10) Pub. No.: US 2025/0337387 A1
(43) Pub. Date: Oct. 30, 2025

(54) CRYSTAL UNIT

(71) Applicant: NIHON DEMPA KOGYO CO., LTD., Tokyo (JP)

(72) Inventors: Akihiro SAKANASHI, Saitama (JP); Motoki OGAWA, Saitama (JP)

(73) Assignee: NIHON DEMPA KOGYO CO., LTD., Tokyo (JP)

(21) Appl. No.: 19/182,595

(22) Filed: Apr. 18, 2025

(30) Foreign Application Priority Data
Apr. 26, 2024 (JP) 2024-072183
Feb. 5, 2025 (JP) 2025-017241
Mar. 5, 2025 (JP) 2025-034326

(51) Int. Cl. H03H 9/10; H03H 9/02; H03H 9/19

(52) U.S. Cl. CPC H03H 9/1021; H03H 9/02102; H03H 9/02133; H03H 9/19

(57) ABSTRACT

A crystal unit includes an AT-cut quartz-crystal vibrating piece, a container, a pedestal, and a conductive adhesive. The quartz-crystal vibrating piece is adhered to the pedestal at two positions along an X-axis of a crystal or at two positions along a Z′-axis of the crystal. Depending on whether the quartz-crystal vibrating piece is adhered to the pedestal at the two positions along the X-axis or is adhered to the pedestal at the two positions along the Z′-axis, the pedestal made of the crystal has the X-axis or one of the Z′-axis or a Z-axis of the crystal in a direction parallel to a plane, has a thickness T with respect to a thickness t of the quartz-crystal vibrating piece of 0.9t≤T≤3.1t, and is adhered to the two adhesion pads in a positional relationship in which the axis of the pedestal is parallel to the first direction.

### CROSS-REFERENCE TO RELATED APPLICATIONS

This application is based on and claims priority under 35 U.S.C. § 119 to Japanese Patent Application No. 2024-72183, filed on Apr. 26, 2024, Japanese Patent Application No. 2025-17241, filed on Feb. 5, 2025, and Japanese Patent Application No. 2025-034326, filed on Mar. 5, 2025. The entire contents of which are incorporated herein by reference.

### TECHNICAL FIELD

This disclosure relates to a crystal unit having a pedestal.

### DESCRIPTION OF THE RELATED ART

An AT-cut crystal unit has been heavily used as a reference signal source of electronic equipment. A typical example of the AT-cut crystal unit includes a container and a quartz-crystal vibrating piece adhered within the container.

The AT-cut crystal unit is required to have higher and higher accuracy characteristics. As one of the countermeasures for achieving the high accuracy, a structure with a pedestal disposed between the quartz-crystal vibrating piece and the container has been proposed.

For example, Japanese Unexamined Patent Application Publication No. 2010-135890 discloses the use of a pedestal having the same expansion coefficient as that of a quartz-crystal vibrating piece as a pedestal (for example, claim 1 in Japanese Unexamined Patent Application Publication No. 2010-135890). Furthermore, there is disclosed the use of a blank having the same cut angle as that of the quartz-crystal vibrating piece as the pedestal (for example, Paragraph 4 and the like in Japanese Unexamined Patent Application Publication No. 2010-135890).

In the structure having the pedestal interposed between the quartz-crystal vibrating piece and the container, the use of the blank having the same cut angle as that of the quartz-crystal vibrating piece as the pedestal is thought to be certainly effective for reducing the heat stress caused by the adhesion structure. However, according to the examination by the inventors of this application, it has been found that further optimization to reduce the heat stress caused by the adhesion structure is necessary.

A need thus exists for a crystal unit which is not susceptible to the drawback mentioned above.

### SUMMARY

According to an aspect of this disclosure, there is provided a crystal unit including an AT-cut quartz-crystal vibrating piece, a container, a pedestal, and a conductive adhesive. The AT-cut quartz-crystal vibrating piece has a planar shape in a quadrilateral shape. The container has two adhesion pads disposed along a first direction. The pedestal is made of a crystal disposed between the quartz-crystal vibrating piece and the two adhesion pads. The conductive adhesive connects the quartz-crystal vibrating piece, the pedestal, and the adhesion pads. The quartz-crystal vibrating piece is adhered to the pedestal at two positions along an X-axis of a crystal or at two positions along a Z′-axis of the crystal. Depending on whether the quartz-crystal vibrating piece is adhered to the pedestal at the two positions along the X-axis or is adhered to the pedestal at the two positions along the Z′-axis, the pedestal made of the crystal has the X-axis or one of the Z′-axis or a Z-axis of the crystal in a direction parallel to a plane, has a thickness T with respect to a thickness t of the quartz-crystal vibrating piece of 0.9t≤T≤3.1t, and is adhered to the two adhesion pads in a positional relationship in which the axis of the pedestal is parallel to the first direction, where, the Z′-axis is an axis displaced from the true Z-axis of the crystal derived from a cut angle of the AT-cut crystal element.

### BRIEF DESCRIPTION OF THE DRAWINGS

The foregoing and additional features and characteristics of this disclosure will become more apparent from the following detailed description considered with reference to the accompanying drawings, wherein:

FIG. 1A to FIG. 1C are drawings for describing a crystal unit 10 according to a first embodiment;

FIG. 2A and FIG. 2B are drawings for describing a relationship between a quartz-crystal vibrating piece and a pedestal according to the disclosure, in particular, a drawing for describing a relationship relating to crystallographic axes of crystals;

FIG. 3 is a drawing for describing a crystal unit 30 according to a second embodiment;

FIG. 4 is a drawing for describing an example of a temperature compensation type crystal controlled oscillator to which the disclosure is applied;

FIG. 5A to FIG. 5C are drawings for describing experiments and analyses according to the disclosure;

FIG. 6A and FIG. 6B are drawings for describing a thickness and a degree of stress reduction of a pedestal made of a crystal;

FIG. 7A to FIG. 7C are drawings for describing a relationship between a distance h between the quartz-crystal vibrating piece and the pedestal made of the crystal and a crystal impedance, and a relationship between an angle θ formed by the quartz-crystal vibrating piece and the pedestal made of the crystal and the crystal impedance;

FIG. 8A to FIG. 8C are drawings for describing a dimension of the pedestal made of the crystal with respect to the quartz-crystal vibrating piece and an excitation electrode, and a modification of a pedestal structure;

FIG. 9A and FIG. 9B are drawings for describing a preferable container and a preferable pedestal; and

FIG. 10A to FIG. 10C are drawings for describing specific examples of quartz-crystal vibrating pieces.

### DETAILED DESCRIPTION

The following describes embodiments according to this disclosure with reference to the drawings. Each drawing used in the description is merely illustrated schematically for understanding this disclosure. In each drawing used in the description, the same reference numeral is attached to the similar component, and its description is omitted in some cases. Structural examples, used members, and the like described in the following explanations are merely preferable examples within the scope of this disclosure. Therefore, this disclosure is not limited to only the following embodiments.

### 1. Embodiments of Crystal Unit

### 1-1. First Embodiment

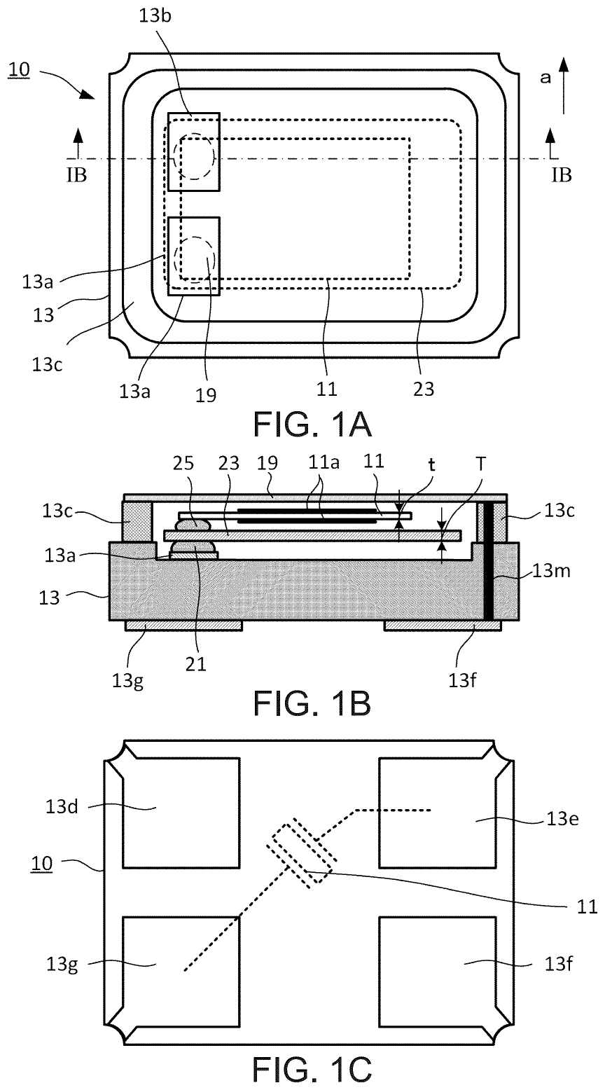

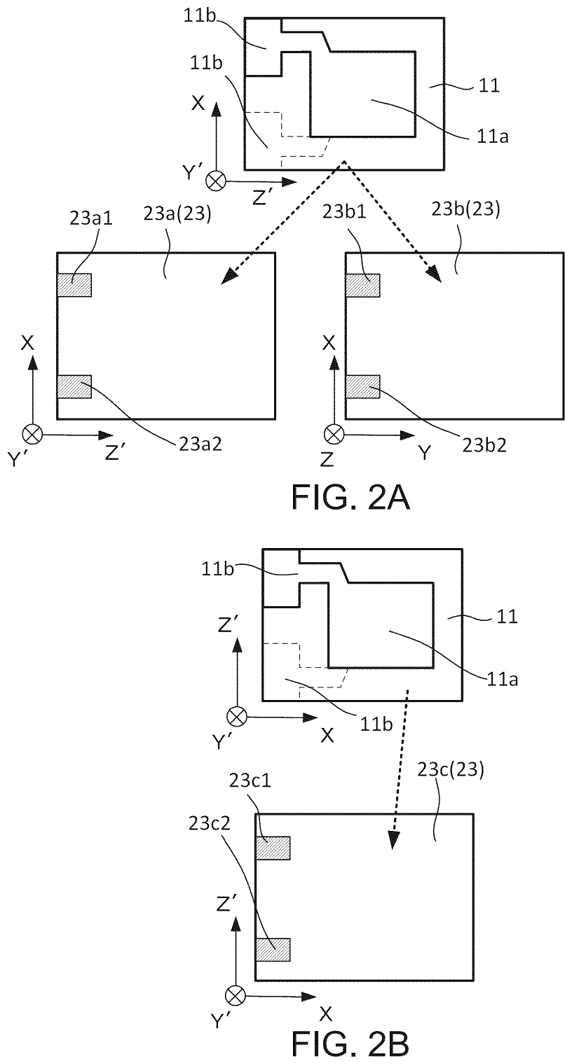

FIG. 1A to FIG. 1C, and FIG. 2A and FIG. 2B are drawings for describing a crystal unit 10 according to a first embodiment. In particular, FIG. 1A is a top view of the crystal unit 10, FIG. 1B is a sectional drawing taken along the line IB-IB in FIG. 1A, and FIG. 1C is a bottom view. FIG. 1A illustrates a state where a lid member 19 is removed. FIG. 2A and FIG. 2B are drawings for describing particularly a relationship between a quartz-crystal vibrating piece 11 and a pedestal 23.

This crystal unit 10 is a crystal unit including the AT-cut quartz-crystal vibrating piece 11 in a quadrilateral shape in plan view, a container 13 having two adhesion pads 13a, 13b provided with a predetermined interval therebetween along a first direction a, the pedestal 23 made of a crystal provided between the quartz-crystal vibrating piece 11 and the two adhesion pads 13a, 13b, and conductive adhesives 21, 25 that connect the quartz-crystal vibrating piece 11, the pedestal 23, and the adhesion pads 13a, 13b. Here, in the case of this example, the first direction a is a direction parallel to a short side direction of the container 13.

While the details will be described below, the quartz-crystal vibrating piece 11 is adhered to the pedestal 23 at two positions along an X-axis of a crystal or two positions along a Z′-axis of the crystal.

While the details will be described below, depending on whether the quartz-crystal vibrating piece 11 is adhered to the pedestal at the two positions along the X-axis, which is a crystallographic axis of the crystal, or the quartz-crystal vibrating piece 11 is adhered to the pedestal at the two positions along the Z′-axis, which is a crystallographic axis of the crystal, the pedestal 23 made of the crystal has the X-axis or one of the Z′-axis or a Z-axis of the crystal in a direction parallel to a plane, is adhered to the two adhesion pads 13a, 13b in a positional relationship where this axis is parallel to the first direction a, and has a thickness T with respect to a thickness t of the quartz-crystal vibrating piece of 0.9t≤T≤3.1t. Note that the Z′-axis is an axis displaced from the true Z-axis of the crystal derived from the cut angle of the AT-cut crystal element.

The quartz-crystal vibrating piece 11 is airtightly sealed, for example, vacuum-sealed with the lid member 19. The following specifically describes respective components.

In particular, as illustrated in FIG. 2A and FIG. 2B, the AT-cut quartz-crystal vibrating piece 11 is in a quadrilateral shape in plan view, a rectangular shape in this example and has a predetermined thickness corresponding to an oscillation frequency, and includes excitation electrodes 11a on front and back principal surfaces and extraction electrodes 11b extracted to one short side of the quartz-crystal vibrating piece from the excitation electrodes 11a.

The quartz-crystal vibrating piece 11 is selected from one that is so-called X-long with a long side parallel to the X-axis, which is the crystallographic axis of the crystal, and a short side parallel to the Z′-axis, which is the crystallographic axis of the crystal, or one that is so-called Z-long with the long side parallel to the Z′-axis of the crystal and the short side parallel to the X-axis of the crystal, or one that has a planar shape in square and has one side parallel to the X-axis of the crystal or parallel to the Z′-axis so as to correspond to the design of the crystal unit.

The container 13 is constituted of a ceramic package having a planar shape in a quadrilateral shape, specifically, a rectangular shape in this case. The container 13 includes a dike 13c along an edge. The quartz-crystal vibrating piece 11 is mounted on the adhesion pads 13a, 13b using a space surrounded by the dike 13c.

The container 13 has four corners on an outer bottom surface where external connecting terminals 13d, 13e, 13f, 13g for connecting the crystal unit 10 to any electronic equipment, for example, an electronic substrate for a mobile phone are provided (see FIG. 1C). Two of the four terminals are electrically connected to the adhesion pad 13a and the adhesion pad 13b in the container via a via-wiring or castellation-wiring (not illustrated). The other two of the four terminals can be used in any way corresponding to the purpose.

The dike 13c of the container 13 has a top surface treated as appropriate for the sealing method. In this case, since seam sealing is used for the sealing, a seam ring (not illustrated) is disposed on the top surface of the dike 13c. The sealing method may be a sealing method by a brazing material such as gold tin. In the case, a metallizing pattern for sealing with gold tin may be disposed on the top surface of the dike 13c. The dike 13c is made of a ceramic. Also, as illustrated in FIG. 1B, a conductor 13m for electrically connecting the lid member 19 with the terminal 13f, which is one terminal for a temperature sensor among external connecting terminals, is embedded on the dike 13c and the predetermined position of the container 13. The external connecting terminal 13f is connected to a ground of an electronic device (not illustrated) connecting the crystal unit 10 and this connecting structure can ensure an electromagnetic shield structure of the crystal unit 10.

The container 13 including the adhesion pads 13a, 13b, the dike 13c, the conductor 13m, and the external connecting terminals 13d, 13e, 13f, 13g can be manufactured by, for example, a ceramic package manufacturing technology.

The lid member 19 can be any member corresponding to the sealing method. When the seam sealing is used for the sealing method, the lid member 19 can be constituted of, for example, a nickel-plated kovar material member.

While the first conductive adhesive 21 and the second conductive adhesive 25 are not limited thereto, it is preferred to use a silicone-based conductive adhesive. For the first conductive adhesive 21 and the second conductive adhesive 25, the same adhesives may be used or the different adhesives may be used, but it is preferred to use the same adhesives.

While the pedestal 23 is not limited thereto, it is preferred to use one in a quadrilateral shape in plan view. This is because machining of the pedestal is easy. However, the planar shape of the pedestal 23 may be any shape including, for example, a triangle, a trapezoidal shape tapered toward the distal end side in width, and the like.

The size of the pedestal 23 is not limited thereto, but in this example, it is planarly larger than the quartz-crystal vibrating piece 11. In some cases, the size of the pedestal is preferably smaller than the quartz-crystal vibrating piece. This will be described later. It is known that there is a preferable value for the thickness of the pedestal 23 according to the examination by the inventors. This will also be described later.

For the pedestal 23, an appropriate one is used depending on whether the quartz-crystal vibrating piece 11 is connected to the pedestal at the two positions along the X-axis of the crystal or the quartz-crystal vibrating piece is connected to the pedestal at the two positions along the Z′-axis of the crystal. This will be specifically described with reference to FIG. 2A and FIG. 2B. The coordinate axes indicated by X, Y′, Z′ in FIG. 2A and FIG. 2B are crystallographic axes of the crystal derived from the AT-cut. The axis Y′ and the axis Z′ indicate that the axes are displaced from the original Y-axis and Z-axis of the crystal corresponding to the cut angle of the AT-cut.

FIG. 2A is a description of the pedestal when the quartz-crystal vibrating piece 11 is connected to the pedestal 23 at the two positions along the X-axis of the crystal. That is, it is an example in which the ends of the extraction electrodes 11b are at the two positions of the quartz-crystal vibrating piece 11 apart from one another along the X-axis of the crystal, and the quartz-crystal vibrating piece 11 is adhered to a pedestal 23a and a pedestal 23b at these positions. The pedestal 23 in this case includes the X-axis of the crystal parallel to the plane and can connect the quartz-crystal vibrating piece 11 at the two positions along this X-axis. Specifically, the pedestal 23 in this case is the pedestal 23a constituted of an AT-cut crystal element illustrated in a lower left side in FIG. 2A, and includes adhesion wirings 23a1, 23a2 at the two positions along the X-axis of the crystal. The pedestal 23 in this case may be the pedestal 23b constituted of a Z-cut crystal element illustrated in a lower right side in FIG. 2A, and include the adhesion wirings 23a1, 23a2 at the two positions along the X-axis of the crystal.

The pedestal is adhered to the adhesion pads and the quartz-crystal vibrating piece 11 is adhered to the pedestal such that the quartz-crystal vibrating piece 11 and the pedestal 23a or 23b have the X-axes of the respective crystals in a positional relationship parallel to the first direction a (see FIG. 1A).

FIG. 2B is an explanatory drawing of the pedestal when the quartz-crystal vibrating piece 11 is connected to the pedestal 23 at the two positions along the Z′-axis of the crystal. A pedestal 23c in this case includes the Z-axis or Z′-axis of the crystal within the plane and can connect the quartz-crystal vibrating piece 11 at the two positions along this Z-axis or Z′-axis. Specifically, the pedestal 23c is constituted of an AT-cut crystal element, and includes adhesion wirings 23c1, 23c2 along the Z′-axis of the crystal of the pedestal corresponding to the extraction electrodes 11b of the quartz-crystal vibrating piece 11.

The pedestal is adhered to the adhesion pads and the quartz-crystal vibrating piece 11 is adhered to the pedestal such that the quartz-crystal vibrating piece 11 and the pedestal 23c have the Z′-axes of the respective crystals in a positional relationship parallel to the first direction a (see FIG. 1A).

Note that, on the respective pedestals 23a, 23b, 23c described above, the X-axis and the Z′-axis of the pedestal are not necessarily truly the same as the X-axis and the Z′-axis of the quartz-crystal vibrating piece. Within the scope of the object of the disclosure, the case where the respective axes of the two have slight angle deviations and the case where parallelism between the two are deviated are allowed.

In the crystal unit 10 of this embodiment, as illustrated in FIG. 1A and FIG. 1B, the pedestal 23 made of the crystal is connected and secured on the container 13 at the positions of the adhesion pads 13a, 13b of the container 13 on one short side in a state of being cantilevered by the first conductive adhesive 21. The quartz-crystal vibrating piece 11 is also connected and secured on the pedestal 23 made of the crystal at the positions of the adhesion wirings (23c1, 23c2) of the pedestal 23 made of the crystal on one short side in a state of being cantilevered by the second conductive adhesive 25. Accordingly, the crystal unit 10 has a structure in which the adhesion pad 13a, the first conductive adhesive 21, one end of the pedestal 23, the second conductive adhesive 25, and one end of the quartz-crystal vibrating piece 11 are in a state of overlapping in a vertical direction and has a structure in which the pedestal 23 made of the crystal and the quartz-crystal vibrating piece 11 are cantilevered on the same one ends. The effect by this structure will be described in detail with reference to experimental results and analysis results by the finite element method later.

### 1-2. Second Embodiment

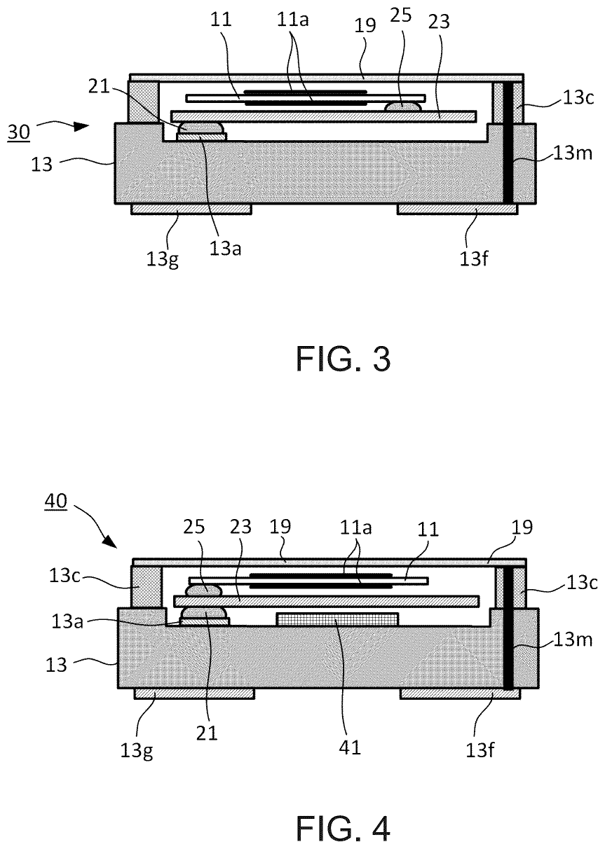

Next, a crystal unit 30, which is a second embodiment, will be described. This will be described with reference to FIG. 3. FIG. 3 is a sectional drawing of the crystal unit 30 corresponding to the drawing illustrated in FIG. 1B.

The crystal unit 10 in the first embodiment has, as illustrated in FIG. 1A to FIG. 1C and as described above, the structure in which the adhesion pads 13a, 13b, the first conductive adhesives 21, and one end of the pedestal 23, the second conductive adhesives 25, and one end of the quartz-crystal vibrating piece 11 are in the state of overlapping in the vertical direction and has the structure in which the pedestal 23 made of the crystal and the quartz-crystal vibrating piece 11 are cantilevered on the same one ends. In contrast to this, the crystal unit 30 of the second embodiment has, as illustrated in FIG. 3, the one end of a pedestal 23d is connected to the adhesion pads 13a, 13b via the first conductive adhesive 21, and the one end of the quartz-crystal vibrating piece 11 is connected to the other end of the pedestal 23d in a longitudinal direction via the second conductive adhesive 25. That is, a bonding point by the first conductive adhesive 21 and a bonding point by the second conductive adhesive 25 are in a structure of being separated and disposed at two ends of the pedestal 23d in the longitudinal direction. Therefore, the adhesion wirings (not illustrated) of the pedestal 23 in this case are in a long shape across the longitudinal direction of the pedestal 23. Since this crystal unit 30 has the structure in which the quartz-crystal vibrating piece 11 is adhered on a portion in a free end side of the pedestal 23, there is a concern when the distal end of the pedestal 23 is swayed. However, an effect similar to or an effect more than that of the crystal unit 10 in reducing the heat stress can be obtained.

### 2. Application Example of Embodiment

FIG. 4 is a drawing for describing an application example of the embodiment, and is a sectional drawing of a temperature compensation type crystal controlled oscillator 40 to which the embodiment is applied. That is, an integrated circuit 41 for temperature compensation is provided in the crystal unit according to the first embodiment described above with reference to FIG. 1A to FIG. 1C and FIG. 2A and FIG. 2B. Since the embodiment is applied to the temperature compensation type crystal controlled oscillator, an effect of a pedestal 43 is added, and therefore, a temperature compensation type crystal controlled oscillator with high accuracy due to the effect can be expected. As it is the temperature compensation type crystal controlled oscillator, the wirings and the number of terminals corresponding thereto are changed, and the description regarding the change is omitted.

### 3. Experimental Results and Analysis Results of Finite Element Method for Describing Features of Embodiment

### 3-1. Regarding Pedestal

One of the features of the embodiment is that a predetermined pedestal made of a crystal is used as the pedestal, and the examination result that has led to this feature will be described below.

### 3-1-1. Frequency Hysteresis Depending on Presence/Absence of Pedestal

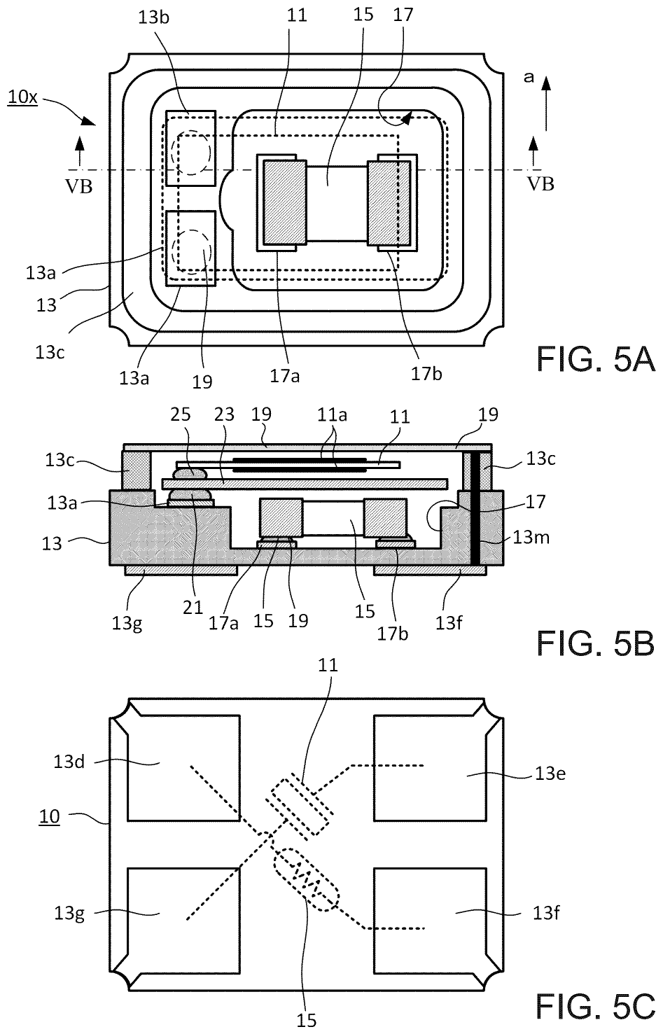

First, the presence/absence of the pedestal was examined. In order to facilitate the examination, a temperature sensor built-in crystal unit 10x (hereinafter referred to as an evaluation sample for short in some cases) as illustrated in a plan view, a sectional drawing, and a bottom view in FIG. 5A, FIG. 5B, and FIG. 5C was used. This evaluation sample 10x has a depressed portion 17 provided at a bottom side portion of the container 13, and has a thermistor 15 as a temperature sensor built-in in the depressed portion 17. The depressed portion 17 has a bottom surface on which terminals 17a, 17b for the thermistor are provided. These terminals 17a, 17b are connected to the external connecting terminal 13d, 13f on the container outer bottom surface via a via-wiring and a castellation-wiring (not illustrated).

As the evaluation samples, the inventors of the application prepared a plurality of evaluation samples of Example having a pedestal structure of the crystal unit 10 described with reference to FIG. 1A to FIG. 1C and FIG. 2A and FIG. 2B and a plurality of evaluation samples of Comparative Example having a crystal unit without using a pedestal, that is, a structure in which the quartz-crystal vibrating piece 11 is directly adhered to the adhesion pads 13a, 13b at the positions of one end of the quartz-crystal vibrating piece 11 via a silicone-based conductive adhesive.

Both Example and Comparative Example are prototyped using a ceramic package of, what is called, a 1612 size. Both Example and Comparative Example have the AT-cut quartz-crystal vibrating piece used in the experiment of X-long, in a size mountable in the 1612 sized ceramic package, with an oscillation frequency of 76.8 MHz (a thickness of the quartz-crystal vibrating piece of approximately 22 μm), and having a predetermined excitation electrode. The used quartz-crystal vibrating piece has an outside dimension of, specifically, approximately 0.75 mm in the X dimension and approximately 0.51 mm in the Z′ dimension. The pedestal used in Example is an AT-cut crystal element having the X dimension of 1.0 mm, the Z′ dimension of 0.8 mm, and the thickness of 40 μm. Here, the 1612 sized ceramic package has an outer shape with approximately 1.6 mm of the long side dimension and approximately 1.2 mm of the short side dimension, and the inside of the 1612 sized ceramic package has the structure described using FIG. 1A to FIG. 1C.

Next, hysteresis characteristics of respective frequency versus temperature characteristics of the evaluation samples of these Example and Comparative Example were measured. While the illustration is omitted, the measurement was performed using a temperature control device including a substrate with a Peltier element and a temperature controller that controls a temperature of the Peltier element, a frequency measurement device, and a temperature measurement device.

Specifically, the evaluation samples of Example and Comparative Example are connected to the substrate having the Peltier element. The frequency measurement device is connected to the terminals 13e, 13g connected to the quartz-crystal vibrating piece 11 among the external connecting terminals (13d to 13g in FIG. 5C) of this evaluation sample, and the temperature measurement device is connected to the terminals 13d, 13f connected to the temperature sensor 15.

Next, the temperature of the Peltier element is raised to t1 degrees to tn (tn>t1) degrees at a predetermined temperature interval and in a predetermined temperature rising condition using the temperature control device, and then immediately is decreased to t1 degrees in the same temperature changing condition as the temperature increase. Actual temperatures of the respective evaluation samples 10x at these temperature rise and temperature decrease were measured using the temperature sensor 15 and the temperature measurement device, and the frequency of the quartz-crystal vibrating piece 11 was measured using the frequency measurement device. On the basis of these measurement results, frequency versus temperature characteristics at temperature rise and frequency versus temperature characteristics at temperature decrease were extracted.

Next, respective frequency differences at the same temperature, that is, frequency hysteresis information of the frequency versus temperature characteristics at temperature rise and the frequency versus temperature characteristics at temperature decrease were obtained, and a mean value of the frequency difference were calculated for each evaluation sample.

Using these mean values, a mean value, the maximum value, the minimum value of the above-described frequency differences of the sample group of Example and a mean value, the maximum value, the minimum value of the above-described frequency differences of the sample group of Comparative Example were obtained. These results are shown in Table 1. The frequency difference is shown in a unit of ppm, which is a ratio obtained by dividing the frequency difference by the oscillation frequency. From Table 1, it is seen that the frequency difference between the temperature rise and the temperature decrease defined above of Example with respect to that of Comparative Example is 0.06/0.026≈0.23, and is as small as approximately one-fifth when compared in the mean values. It is seen that the maximum value of Example with respect to that of Comparative Example is 0.09/0.96≈0.09, and is as small as approximately one-eleventh as well.

TABLE 1

| | Frequency difference | | |
|---|---|---|---|
| | between temperature rise | | |
| | and temperature decrease | | |
| | Mean | Maximum | Minimum |
| | value | value | value |
| Example (AT-cut crystal element pedestal) | 0.06 | 0.09 | 0.02 |
| Comparative Example (no pedestal) | 0.26 | 0.96 | 0.01 |

Unit: ppm

### 3-1-2. Material of Pedestal and Crystallographic Axis of Pedestal

The following evaluations by the finite element method were performed as another evaluation. Four types of analytical models, which are models of the finite element method imitating the crystal unit 10 described using FIG. 1A to FIG. 1C, with crystallographic axis conditions of the crystal in a direction of arrangement of the two bonding points of the AT-cut quartz-crystal vibrating piece, and conditions of a material and a crystallographic axis of the pedestal being set as illustrated in Table 2 below were manufactured. Von Mises stresses generated at center points of the quartz-crystal vibrating pieces in the analytical models when the respective analytical models were changed in temperature from 25° C. to 105° C. were obtained. The results are shown in Table 2.

TABLE 2

| | | | | Crystallographic axis of | |
|---|---|---|---|---|---|
| | Quartz-crystal | Axis connecting | Material | pedestal adjusted for quartz- | Stress |
| | vibrating p | two bonding | of pedestal | crystal vibrating piece | (kPa) |
| Analytical | X-long | Z′-axis | Ceramic | Amorphous, therefore | 365.9 |
| Model 1 | | of crystal | | no applicable axis | |
| Analytical | X-long | Z′-axis | Crystal Z- | Z′-axis being perpendicular | 385.7 |
| Model 2 | | of crystal | cut plate | to plate surface of pedestal, | |
| | | | | therefore no applicable axis | |
| Analytical | Z-long | X-axis | Crystal Z- | X-axis of Z-cut plate | 11.7 |
| Model 3 | | of crystal | cut plate | | |
| Analytical | X-long | Z′-axis | Crystal AT- | Z′-axis of AT-cut plate | 9.8 |
| Model 4 | | of crystal | cut plate | | |

From Table 2, it is seen that the stresses generated at the centers of the quartz-crystal vibrating pieces due to the above-described temperature change are approximately 366 to 386 kPa in Analytical Model 1 and Analytical Model 2, on the other hand, are approximately 10 kPa in Analytical Model 3 and Analytical Model 4, which are as small as approximately one-thirty seventh. It is seen that using the crystallographic axis equivalent to a line segment connecting the two bonding points of the quartz-crystal vibrating piece and the pedestal made of the crystal having the crystallographic axis that matches this crystallographic axis in an appropriate axis relationship enables reduction of the stress.

Accordingly, from the results in Table 1 and the results in Table 2, it is seen that appropriately selecting and using the pedestal made of the AT-cut crystal or the pedestal made of the Z-cut crystal as the pedestal taking the adhesion direction of the two points of the AT-cut quartz-crystal vibrating piece into account is effective in reducing the heat stress at the adhesion structure part of the crystal unit.

### 3-1-3. Pedestal Thickness and Stress in Quartz-Crystal Vibrating Piece

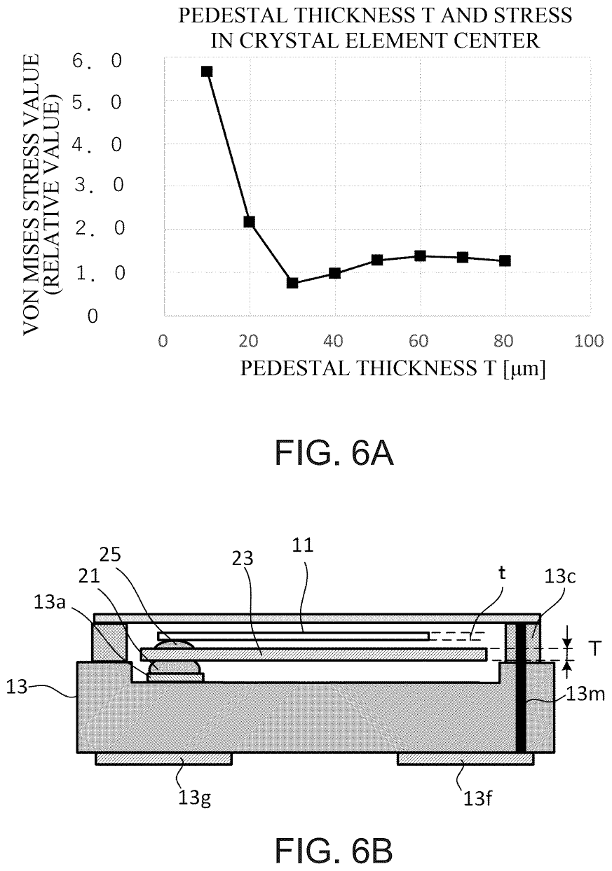

As yet another evaluation by the finite element method, how the thickness of the pedestal made of the crystal affects the stress in the quartz-crystal vibrating piece was examined. Specifically, eight types of analytical models, which are Analytical Model 4 in Table 2, with different thicknesses T of the pedestal made of the AT-cut crystal differing from one another by 10 μm increments from 10 μm to 80 μm were prepared. Von Mises stresses generated at center points of the quartz-crystal vibrating pieces in the models when the respective analytical models were changed in temperature from 25° C. to 105° C. were obtained. FIG. 6A is a drawing showing the results, and is a drawing indicating the thickness of the pedestal by the horizontal axis and the stress value (the relative value) by the vertical axis. FIG. 6B is a drawing showing definitions of the thickness T of the pedestal 23 and the thickness t of the quartz-crystal vibrating piece 11.

FIG. 6A shows the tendency that, when the stress when the thickness T of the pedestal is 10 μm is used as a reference, the stress is approximately one-third when the thickness T of the pedestal is 20 μm, the stress is approximately one-sixth when the thickness T of the pedestal is 30 μm, the stress is increased to approximately one-fifth of the reference up to 60 μm of the thickness T of the pedestal, and the stress is reduced when the thickness T of the pedestal further increases.

Accordingly, it is possible to say that the thicker the thickness T of the pedestal is, the better it is, but there is a limit as if it is too thick, the pedestal fails to fit within the container of the crystal unit. By examining the proper value of the thickness of the pedestal on the basis of these, the following is concluded.

In the case of this analytical model, the thickness of the quartz-crystal vibrating piece is approximately 22 μm (derived from the oscillation frequency of 76.8 MHz), and therefore, the thickness of the quartz-crystal vibrating piece of 22 μm is set as a reference. Then, the thickness T of the pedestal is preferably 20 μm≤T or a thickness equal to or more than the thickness of the quartz-crystal vibrating piece, and by considering it to be housed in the container, the thickness T of the pedestal is preferably 20 μm≤T≤70 μm or the thickness of the quartz-crystal vibrating piece≤T≤70 μm. When the thickness T of the pedestal is in a range from approximately 20 μm, which is slightly thinner than the thickness of the quartz-crystal vibrating piece, to 60 μm, the stress is smaller than the other cases, and therefore, the thickness T of the pedestal is preferably 20 μm≤T≤60 μm, and is more preferably 30 μm≤T≤60 μm. It is also possible to conclude as follows by generalizing the above-described examination results.

When the thickness of the quartz-crystal vibrating piece is t, and the thickness of the pedestal is T, T≥0.9t is preferred. It is preferably 0.9t≤T≤3.1t or t≤T≤3.1t, more preferably 0.9t≤T≤2.7t or t≤T≤2.7t, and further more preferably 1.3t≤T≤2.7t. Here, the numerical value of 0.9 is based on 20/22≈0.9 in the above-described numerical value. The numerical value of 3.1 is based on 70/22≈3.18. The numerical value of 2.7 is based on 60/22≈2.7. The numerical value of 1.3 is based on 30/22≈1.36.

3-1-4. Distance between Quartz-Crystal Vibrating Piece and Pedestal, and Angle Formed by Them

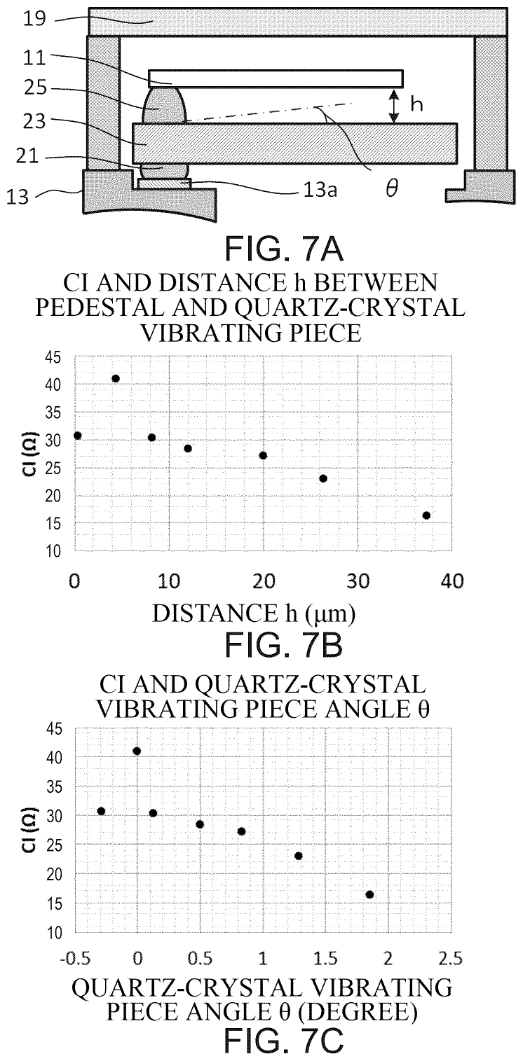

The following evaluation was performed as another evaluation. FIG. 7A to FIG. 7C are drawings for the description thereof. Respective crystal impedances (CI) of the samples of Example prototyped in the paragraph 3-1-1 described above were measured. As illustrated in FIG. 7A, a distance h between the distal end of the quartz-crystal vibrating piece 11 and the pedestal 23 and an angle θ formed by the quartz-crystal vibrating piece 11 and the pedestal 23 were measured for each of the samples.

FIG. 7B is a drawing showing a relationship of the CI to the distance h between the distal end of the quartz-crystal vibrating piece 11 and the pedestal 23 on the basis of the above-described measurement results. From FIG. 7B, it can be said that the CI improves when the distance h is large to some extent. If the distance h is small, there is a concern of a failure, such as a damage, caused by the distal end of the quartz-crystal vibrating piece 11 contacting the pedestal 23 when an impact affects the crystal unit, and therefore, the distance h is preferred to be large to some extent from this point of view.

In the case of this example, it is said that the distance h should be set to an appropriate value that is equal to or more than 20 μm and takes the limitation of the container in the height direction and the like into account from FIG. 7B. Considering this respect with the thickness of the quartz-crystal vibrating piece prototyped this time of 22 μm, it is also said that the distance h should be set to an appropriate value that is equal to or more than 20/22≈0.9t with respect to the thickness t of the quartz-crystal vibrating piece.

FIG. 7C is a drawing showing a relationship of the CI to the angle θ formed by the quartz-crystal vibrating piece 11 and the pedestal 23 on the basis of the above-described measurement results. From FIG. 7C, it can be said that the CI improves when the angle θ is large to some extent. As described above, it can be said that the angle θ is preferred to be large to some extent also from the view point of enhancing the impact resistance. In the case of this example, it can be said from FIG. 7C that the angle θ should be an appropriate angle of 0.5 degrees or more.

It is considered that the conductive adhesive 25 is less likely to flow to the center side of the quartz-crystal vibrating piece 11 if the distance h or the angle θ is set to large to some extent, thereby being considered to successfully reduce the effect of the conductive adhesive to the vibrator to allow suppression of degraded CI.

When the distance h is small, a negative effect of stray capacitance from the pedestal to the excitation electrode occurs in some cases, and therefore, the distance h should be large to some extent by taking the countermeasure thereof into account.

### 3-1-5. Size and Shape of Pedestal

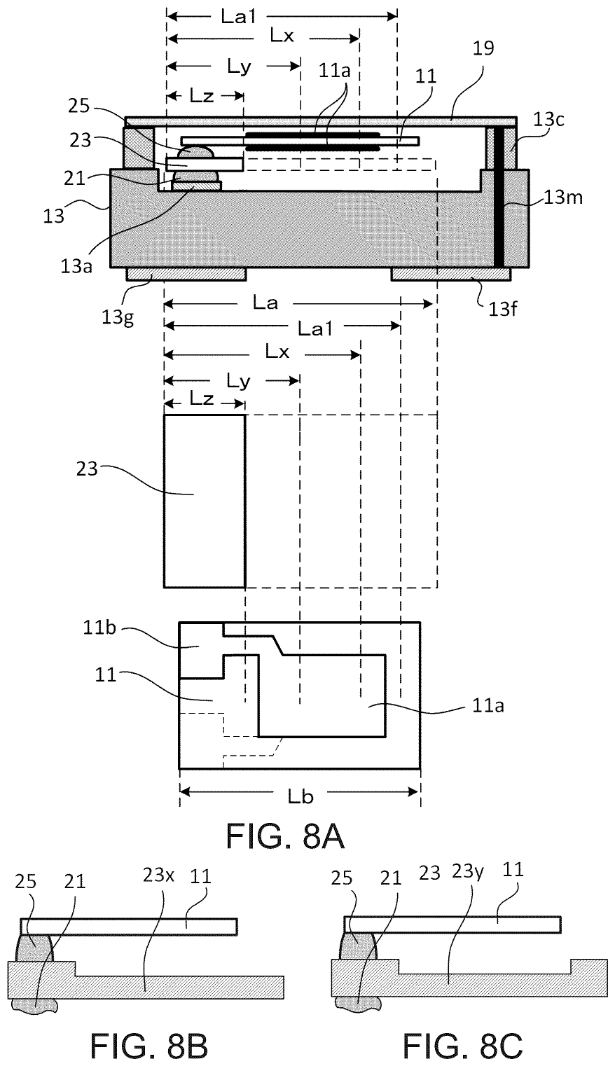

The embodiments described above have described the examples in which the pedestal is larger than the quartz-crystal vibrating piece. However, it is considered that the pedestal does not have to be that large as long as it is in the range where the effect of the heat stress to the quartz-crystal vibrating piece can be reduced and there is no problem in adhesive strength, and from the reason of, for example, avoiding the contact between the quartz-crystal vibrating piece and the pedestal. The pedestal does not have to be that large even when the effects of the distance h and the angle θ described above are taken into account. The consideration relating to the size of this pedestal will be described with reference to FIG. 8A.

FIG. 8A is a drawing illustrating a sectional drawing of the crystal unit 10 corresponding to FIG. 1B, a plan view of the pedestal 23, and a plan view of the quartz-crystal vibrating piece 11 together. A long side dimension of the quartz-crystal vibrating piece 11 is Lb, and various dimension examples of the pedestal on the long side are indicated. In FIG. 8A, a longitudinal dimension La of the pedestal indicated by La shows a dimension larger than the longitudinal dimension Lb of the quartz-crystal vibrating piece.

As described above, when it is considered that the pedestal does not have to be that large as long as it is in the range where there is no problem in adhesive strength by considering reduction of the effect of the heat stress to the quartz-crystal vibrating piece, the countermeasure for impact resistance, and the countermeasure for stray capacitance, the example of FIG. 8A illustrates four examples with different distal end positions of the pedestal 23 with respect to the distal end position of the quartz-crystal vibrating piece 11 and the distal end position of the excitation electrode 11a.

A first example has a long side dimension La1 of the pedestal with which the distal end position of the pedestal 23 is positioned between the distal end position of the quartz-crystal vibrating piece and the distal end position of the excitation electrode.

A second example has a long side dimension Lx of the pedestal with which the distal end position of the pedestal 23 is positioned between the distal end position of the excitation electrode and the center position of the excitation electrode.

A third example has a long side dimension Ly of the pedestal with which the distal end position of the pedestal 23 is positioned between the center position of the excitation electrode and a position at an end of the excitation electrode on a side of the conductive adhesive 25.

A fourth example has a long side dimension Lz of the pedestal with which the distal end position of the pedestal 23 is positioned between the position at the end of the excitation electrode on the side of the conductive adhesive 25 and the conductive adhesive 25.

Selecting any one of La1, Lx, Ly, or Lz for the long side dimension of the pedestal may be determined corresponding to the design of the crystal unit 10. However, it is considered that the long side dimension of the pedestal should be Lz when considering that the pedestal is only necessary to be in the range where the reduction of effect of the heat stress to the quartz-crystal vibrating piece and the like are achieved and there is no problem in adhesive strength. That is, it is considered that the distal end position of the pedestal should be positioned between the position at the end of the excitation electrode on the side of the conductive adhesive 25 and the conductive adhesive 25 so as to avoid the pedestal 23 from being opposed to the excitation electrode 11a.

For the three-dimensional structure of the pedestal, as illustrated in FIG. 8B and FIG. 8C, the pedestal may be a pedestal 23x (FIG. 8B) having the thickness of the pedestal thinned from a middle in the longitudinal direction to the other end, for example, from a near side opposed to the excitation electrode to the other end, or a pedestal 23y (FIG. 8C) having the thickness of the pedestal thinned in a central region in the longitudinal direction, for example, in a region a bit larger than a region opposed to the excitation electrode.

While the above-described embodiment has described the example in which the oscillation frequency is 76.8 MHz, the present disclosure is applicable even in the case of another frequency. For example, the present disclosure is effective to those with various frequency bands proven as a reference signal source. Furthermore, the present disclosure is more and more effective to those with further high frequency, which will be utilized in the future, for example, those with 152 MHz band and the like.

While the above-described embodiments exemplarily described those having the outside dimension of the package in a 1612 size, the present disclosure is applicable to those in other sizes. The present disclosure is applicable to those having the outside dimension of the package in a 1210 size, in a 1008 size, in a further smaller size, and in a size larger than the 1612 size. In the case of those in a small size in particular, the effect of the heat stress further increases as the quartz-crystal vibrating piece is smaller, and therefore, it is considered that the application of the present disclosure facilitates achieving reduction of the heat stress.

### 4. Another Preferable Container and Preferable Pedestal

The above-described embodiments have exemplarily described the container 13 described with reference to FIG. 1A, FIG. 1B, and the like as one example of the container. That is, there has been exemplarily described the container 13 having the planar shape in the quadrilateral shape, specifically, the rectangular shape, including the dike 13c made of a ceramic along the edge, and including the seam ring (not illustrated) on the top surface of the dike 13c. As one example of the pedestal, the pedestal 23 described with reference to FIG. 2A and FIG. 2B, FIG. 8A to FIG. 8C, and the like has been exemplarily described. That is, the pedestal 23 in the rectangular shape in plan view having the wiring 23a1 and the like extracted to the side surface on the dike 13c side of the container 13 has been exemplarily described.

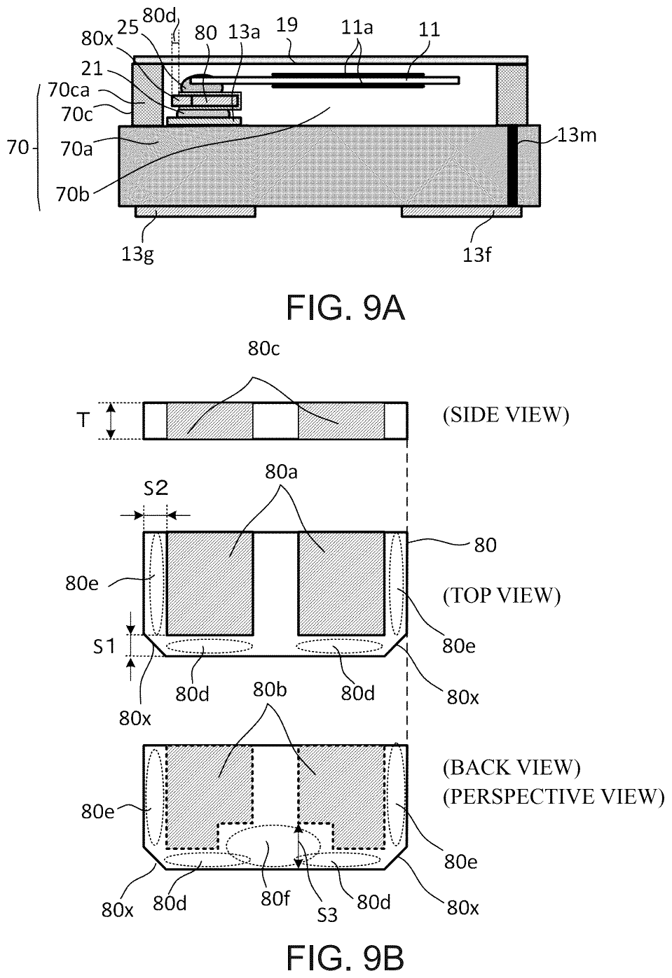

However, when further characteristic improvement and size reduction of the piezoelectric device are attempted, for example, the container and the pedestal having the following structures are preferred. The following describes them with reference to FIG. 9A and FIG. 9B. Here, FIG. 9A is a sectional drawing corresponding to FIG. 1B in order to describe a preferred container 70. FIG. 9B is a side view, a top view, and a back view (a perspective view) in order to describe a preferred pedestal 80.

The preferred container 70 includes a main body portion 70a made of a ceramic, and a ring-shaped member 70c made of a metal that is connected to the main body portion 70a to house the quartz-crystal vibrating piece and serves as a side wall of a depressed portion 70b in a quadrilateral shape in plan view. In detail, the main body portion 70a has a planar shape in a quadrilateral shape, specifically a rectangular shape. The ring-shaped member 70c made of the metal is connected to the main body portion 70a with, for example, a brazing material along an edge of a surface of the main body portion 70a on which the adhesion pad 13a and the like are formed. Accordingly, the ring-shaped member 70c made of the metal constitutes the side wall of the depressed portion 70b. Therefore, a planar shape of the ring-shaped member 70c made of the metal has a shape similar to the dike 13c as illustrated in FIG. 1A. The ring-shaped member 70c made of the metal is typically made of a kovar material. Also, as illustrated in FIG. 9A, the conductor 13m is embedded in a predetermined position of the main body portion 70a made of a ceramic for electrically connecting the ring-shaped member 70c made of the metal with the terminal 13f, which is one terminal among the external connecting terminals. The external connecting terminal 13f is connected to a ground of an electronic device (not illustrated) connected to the crystal unit 10 and this connecting structure can ensure an electromagnetic shield structure of the crystal unit 10.

The two adhesion pads 13a, 13b (see FIG. 1A to FIG. 1C) are provided on and along a portion of the main body portion 70a on a side of a first side wall 70ca corresponding to a first side of the ring-shaped member 70c.

In the case of this preferred container 70, the depressed portion in which the quartz-crystal vibrating piece 11 is mounted is surrounded by the ring-shaped member 70c made of the metal, and thus, in combination with the metallic lid as the lid member 19, advantages of a stronger electromagnetic shield and the like are obtainable. Accordingly, electromagnetic shield resistance of the crystal unit can be enhanced. The depressed portion (cavity) region in which the quartz-crystal vibrating piece 11 is mounted can be defined by the metallic ring, and therefore, a desired depressed portion can be easily formed. Furthermore, while the crystal unit 10 according to the embodiment, as illustrated in FIG. 1A, uses the dike 13c and seal rings (not illustrated), in the case of the container 70, the use of the ring-shaped member made of the metal instead of the dike 13c makes it easier to achieve a low profile of the crystal unit.

On the other hand, the preferred pedestal 80 includes first wiring patterns 80a for connection with the quartz-crystal vibrating piece on a first surface, second wiring patterns 80b for connection with the container, specifically for connection with the two adhesion pads 13a, 13b on a second surface opposite of the first surface, and third wiring patterns 80c that connect the first wiring patterns 80a and the second wiring patterns 80b to the side wall, and the third wiring patterns 80c are provided on a side wall of the pedestal 80 positioned on the opposite side of a side wall opposed to the first side wall 70ca.

The preferred pedestal 80 further includes cut-out portions 80x at two ends of the side wall opposed to the first side wall 70ca. The cut-out portion 80x is preferably constituted of a C-chamfered portion. The size of the cut-out portion 80x is not limited thereto, for example, is 20 μm to 70 μm in C-dimension, and is preferably approximately 30 μm to 50 μm.

Each of the first wiring pattern 80a and the second wiring pattern 80b includes a retreat portion 80d that retreats from an edge of the pedestal 80 to the center side of the pedestal 80 on at least a side of the first side wall 70ca. The retreat portion 80d has a retreat dimension S1 that is only necessary to be a dimension enough for avoiding the first wiring pattern 80a from contacting (short-circuiting) the metallic ring-shaped member 70c even when the pedestal 80 contacts the metallic ring-shaped member 70c. If the retreat dimension S1 is too large, the areas of the wiring patterns are reduced, which is unpreferable. The dimension is not limited thereto, and the retreat dimension S1 is preferably, for example, approximately 30 μm to 50 μm.

Each of the first wiring pattern 80a and the second wiring pattern 80b further includes a retreat portion 80e on the pedestal 80 on a side of two side walls intersecting with the side wall opposed to the first side wall 70ca of the container. The retreat portion 80e has a retreat dimension S2 that may be determined similarly to the above-described dimension S1. S1 and S2 may have the same dimension or may have different dimensions. In addition to the retreat portion 80d, the second wiring pattern 80b has a retreat portion 80f having a retreat dimension S3 larger than the retreat dimension of the retreat portion 80d in a center side of the pedestal 80 from the edge of the pedestal 80 near the center of the side where the retreat portion 80d of the pedestal 80 is provided. This retreat portion 80f is a retreat portion for avoiding the second wiring pattern 80b from being damaged by a snapping tool used when each pedestal is snapped off from a wafer after a large number of the pedestals 80 are manufactured in a wafer form. The width and the retreat dimension S3 of this retreat portion 80f are determined by taking the size of the snapping tool into account. However, if the width and the retreat dimension S3 of the retreat portion 80f are too large, the area of the second wiring pattern 80b becomes narrow, which is unpreferable in terms of conductivity, and therefore, this should also be considered for these dimensions.

With the above-described preferred pedestal 80, the pedestal can be arranged close to the edge of the wall of the container 70 even when the container 70 having the side wall of the first depressed portion 70b constituted of the metallic ring-shaped member 70c is used. This is because the preferred pedestal 80 includes the above-described predetermined retreat portion 80d and the like and/or the cut-out portion 80x, even though the pedestal is arranged close to the edge of the wall of the container 70, the first wiring pattern 80a, the second wiring pattern 80b, and the third wiring pattern 80c of the pedestal 80 are not short-circuited with the metallic ring-shaped member 70c. Accordingly, the pedestal 80 can be easily mounted even if the mounting margin onto the container 70 is reduced due to the increasingly reduced size of the crystal unit.

The preferred container 70 and the preferred pedestal 80 may surely be used instead of the container 13 and the pedestal 23 of the various crystal units described with reference to FIG. 3, FIG. 4, and FIG. 5A to FIG. 5C.

While the above-described quartz-crystal vibrating piece 11 has a uniform thickness and a planar shape in a rectangular shape, the shapes of the crystal units are not limited to the above examples.

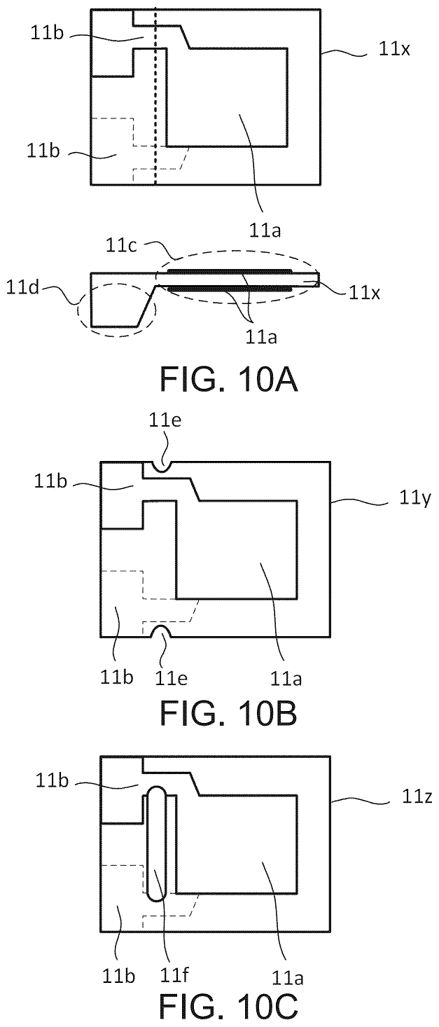

As illustrated in FIG. 10A, for example, the quartz-crystal vibrating piece may have a so-called single-side moment frame structure, which has a vibrator 11c having a thickness corresponding to an oscillation frequency and a supporting portion 11d having a larger thickness compared with the vibrator 11c. Also, as illustrated in FIG. 10B, the quartz-crystal vibrating piece may have a structure having cut-out portions 11e between a vibrator and a supporting portion of the quartz-crystal vibrating piece. Furthermore, as illustrated in FIG. 10C, the quartz-crystal vibrating piece may have a structure having a through hole 11f between a vibrator and a supporting portion of the quartz-crystal vibrating piece. The cut-out portions 11e and the through hole 11f may be disposed on a quartz-crystal vibrating piece having a uniform thickness or may be disposed on the quartz-crystal vibrating piece having the single-side moment frame structure as illustrated in FIG. 10A.

With the embodiments, the crystal unit in which s a cantilever support structure is heavily used is achievable. In the cantilever support structure, the pedestal made of the crystal is adhered to the adhesion pads in a cantilever manner, and the AT-cut quartz-crystal vibrating piece is adhered to this pedestal made of the crystal in a cantilever manner.

Moreover, the crystal unit that has the structure in which, depending on whether the quartz-crystal vibrating piece is connected to the pedestal at the two positions along the X-axis of the crystal or is connected to the pedestal at the two positions along the Z′-axis of the crystal, the pedestal made of the crystal that has the axis corresponding to this axis in the direction parallel to the plane and has the predetermined thickness is used, and the quartz-crystal vibrating piece and the pedestal made of the crystal are adhered in the positional relationship in which the crystallographic axis of the quartz-crystal vibrating piece and the crystallographic axis of the pedestal are in the parallel relationship is achievable. Accordingly, the quartz-crystal vibrating piece and the pedestal made of the crystal can be arranged in a state where the crystallographic conditions of the quartz-crystal vibrating piece and the pedestal made of the crystal in the portions between the two bonding points considered to be the most susceptible to the effects of the heat stress and the like are close to one another. Therefore, the effects of thermal expansion coefficients and the like can be reduced compared with the otherwise case. Moreover, since the pedestal has the predetermined thickness, as can be seen also from the experimental results and the analysis results described above, the heat stress reduction effect is further achievable, and moreover, increase in the thickness of the crystal unit can be suppressed.

Accordingly, the crystal unit having the novel structure that can further achieve the reduction of heat stress can be provided.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A crystal unit, comprising:
an AT-cut quartz-crystal vibrating piece, having a planar shape in a quadrilateral shape;
a container, having two adhesion pads disposed along a first direction;
a pedestal made of a crystal, disposed between the AT-cut quartz-crystal vibrating piece and the two adhesion pads; and
a conductive adhesive that connects the AT-cut quartz-crystal vibrating piece, the pedestal, and the adhesion pads,
wherein
the AT-cut quartz-crystal vibrating piece is adhered to the pedestal at two positions along an X-axis of a crystal or at two positions along a Z′-axis of the crystal, and
depending on whether the AT-cut quartz-crystal vibrating piece is adhered to the pedestal at the two positions along the X-axis or is adhered to the pedestal at the two positions along the Z′-axis, the pedestal made of the crystal has the X-axis or one of the Z′-axis or a Z-axis of the crystal in a direction parallel to a plane, has a thickness T with respect to a thickness t of the AT-cut quartz-crystal vibrating piece of 0.9t≤T≤3.1t, and is adhered to the two adhesion pads in a positional relationship in which the axis of the pedestal is parallel to the first direction, where the Z′-axis is an axis displaced from a true Z-axis of the crystal derived from a cut angle of an AT-cut crystal element.

2. The crystal unit according to claim 1, wherein
the thickness T of the pedestal is 1.3t≤T≤2.7t.

3. The crystal unit according to claim 1, wherein
the pedestal is an AT-cut crystal element and is adhered to the two adhesion pads at two points along an X-axis of a crystal of the AT-cut crystal element.

4. The crystal unit according to claim 1, wherein
the pedestal is an AT-cut crystal element and is adhered to the two adhesion pads at two points along a Z′-axis of a crystal of the AT-cut crystal element.

5. The crystal unit according to claim 1, wherein
the pedestal is an Z-cut crystal element and is adhered to the two adhesion pads at two points along an X-axis of a crystal of the Z-cut crystal element.

6. The crystal unit according to claim 1, wherein
the pedestal has a thickness selected from thicknesses from 30 μm to 60 μm.

7. The crystal unit according to claim 1, wherein
the pedestal has a size with which a distal end is positioned on a side of the adhesion pads with respect to a center of an excitation electrode included in the AT-cut quartz-crystal vibrating piece.

8. The crystal unit according to claim 1, wherein
the pedestal has a size with which a distal end is positioned on a side of the adhesion pads with respect to an excitation electrode included in the AT-cut quartz-crystal vibrating piece.

9. The crystal unit according to claim 1, wherein
the pedestal has a size with which a distal end is positioned on a side of the adhesion pads with respect to an excitation electrode included in the AT-cut quartz-crystal vibrating piece, and has a thickness selected from thicknesses from 30 μm to 60 μm.

10. The crystal unit according to claim 1, wherein
the container includes:
a main body portion made of a ceramic; and
a ring-shaped member made of a metal, and the ring-shaped member is connected to the main body portion to house the AT-cut quartz-crystal vibrating piece and serves as a side wall of a depressed portion in a quadrilateral shape in plan view,
wherein the two adhesion pads are disposed on a side of a first side wall corresponding to a first side of the ring-shaped member.

11. The crystal unit according to claim 1, wherein
the container includes:
a main body portion made of a ceramic; and
a ring-shaped member made of a metal that is connected to the main body portion to house the AT-cut quartz-crystal vibrating piece and serves as a side wall of a depressed portion in a quadrilateral shape in plan view,
wherein the two adhesion pads are disposed on a side of a first side wall corresponding to a first side of the ring-shaped member, and
wherein the pedestal includes:
a first wiring pattern for connection with the AT-cut quartz-crystal vibrating piece on a first surface;
a second wiring pattern for connection with the container on a second surface opposite of the first surface; and
a third wiring pattern that connects the first wiring pattern and the second wiring pattern to a side wall, and the third wiring pattern is disposed on a side wall of the pedestal positioned on an opposite side of a side wall opposed to the first side wall.

12. The crystal unit according to claim 10, further comprising:
cut-out portions, being disposed at two ends of the side wall of the pedestal opposed to the first side wall.

13. The crystal unit according to claim 11, wherein
the first wiring pattern and the second wiring pattern each include: a retreat portion that retreats to a center side from an edge of the pedestal at least on a side of the first side wall of the pedestal.
